(19) United States
(12) Patent Application Publication
(10) Pub. No.: US 2010/0185404 A1
(43) Pub. Date: Jul. 22, 2010

(54) Method of predicting failures in components

(76) Inventor: Len G. Losik, Salinas, CA (US)

Correspondence Address: LEN LOSIK, 12 GLEN FALLS CIRCLE, SALINAS, CA, 93906, US

(21) Appl. No.: 12/231,283

(22) Filed: Sep. 2, 2008

(51) Int. Cl. G01R 31/00

(52) U.S. Cl. 702/58

(57) ABSTRACT

The present invention predicts circuit failure in an electrical or electromechanical system by interpreting test measurement information from component(s) that have begun to change operating behavior as beginning to fail. Electrical components that are changing in electrical properties are diagnosed as beginning to fail leading to an operational circuit condition that is out of specification. Circuit failure prediction using this knowledge is called Prognostics. With this knowledge of an impending failure, circuit turn off, repair or replacement of the equipment that the circuit is in can be done before the circuit/equipment fails averting loss of service. This invention is superior to commonly used circuit diagnostics which are usually used on already failed electrical circuits to determine component failure until after the circuit has failed causing a loss of service. Traditional circuit diagnostics are used to determine which component has failed after the circuit fails to operate according to specifications making Prognostics superior over diagnostics.

### TECHNICAL FIELD

The present invention relates to predicting failures in components. More particularly, the present invention relates to predicting failures in electrical and electromechanical equipment. Even more particularly, the present invention relates to predicting failures in electrical and electromechanical equipment by interpreting test measurement information from components that have begun to change operating behavior.

### BACKGROUND ART

Electrical circuits are designed to provide many functions. The remote control for the television has electrical circuits, as does the toaster, telephone, electrical frying pans, radios, cell phones and computers. Electrical and electromechanical circuits use electrical current to function. Current flows in circuits because of a voltage applied to the wires and the electrical components. Electrical circuits consists of components such as resistors, capacitors, inductors, transistors, diodes, LED's, etc., attached to each other usually by wires or other means. Each component has a specific function and performance value provided by the manufacturer. The sum of the components and connections consist of the circuit. Each electrical component is rated with a specific value for performance with a tolerance specified by the manufacturer. To make sure that a circuit will function with all the components operating at one end of the tolerances or the other, a worst-case circuit analysis may be completed to ensure the circuit will operate in a specified manner. For electromechanical devices, electronic components may be incorporated with mechanical devices for operations.

Sometimes electrical circuits will fail and not provide the functionality that they were designed to provide. When this happens, the circuit can be analyzed to determine what is the cause of the failure. Circuit analysis is employed to determine which component(s) or wire has failed to operate using test equipment to measure electrical properties of circuits such as oscilloscopes, voltmeters, amp meters and logic analyzers. When diagnostics is done, there is a loss of service from the circuit that has failed.

The ability of the circuit to operate as it is designed for can be determined by evaluating the operating performance of the circuit using test equipment to access the information. If the performance of the circuit changes over time after the circuit has had a chance to stabilize electrically, it is an indication that one or more than one component(s) may be changing its operating behavior. Circuit behavior is dynamic caused by circuit LC and RC time constants.

However, the change in behavior discernable with Prognostics is due to component wear out failure. This change in operating behavior from the manufacturer's specified performance is interpreted as a component failure rather than simply circuit noise. Under Prognostics, a circuit fails when it is no longer able to function as designed to the level of performance specified by the manufacturer.

### DISCLOSURE OF INVENTION

Electrical component manufacturers test their components in many ways before shipping them to their customers to verify that their electrical parts will operate for the duration and the performance they specify to their customers. Because there are so many components manufactured at one time, it is not feasible to test every component so special testing is done to quantify the reliability of all the components for use without testing every component. Manufacturers may complete lot testing for their parts they manufacture. Some components out of a lot of components are tested to determine the failure rate resulting in the quality of their products. The results of lot component testing are generalized to the performance of all the components in the lot. In this way, purchasers of the components can be assured of the quality of the components that they are purchasing.

All electrical component failures do not occur right away. As electrical components operate they are subjected to stress from heat, which increases the chemical reactions that occur in components that leads to a change in the molecular make up and eventually component failure. All electrical components will fail eventually. Some electrical components will operate for the duration of their design life. Some components will fail immediately at power up. Some components will operate for a short time and then fail. Since each component is unique, each component has its own time period that it will operate to specifications also referred to as a design life. Some components never operate to specification and fail immediately. Some components will operate within specification for the entire design life, some will operate for longer than the design life and some will operate for less than the design life.

The present invention predicts future failures in electronic circuits where components begin to change in operating behavior. The present invention is able to identify the start of the component changing operating behavior by comparing stable non-failure behavior prior to the start of the failure behavior and discriminating the difference between the two behaviors and finding the point in time when the change in operating behavior began.

### BRIEF DESCRIPTION OF THE DRAWING

For a better understanding of the present invention, reference is made to the below referenced accompanying Drawing. Reference numbers refer to the same or equivalent parts of the present invention throughout the several figures of the Drawing.

FIG. 1 illustrates an example of a telemetry circuit to be added to a primary circuit, in accordance with the present invention.

FIG. 2 illustrates an example of the equipment made up of many electrical circuits forming a complex system, in accordance with the present invention.

FIG. 3 illustrates an example of a thermistor circuit added to a primary circuit to determine circuit temperature, in accordance with the present invention

FIG. 4 illustrates an example of a schematic diagram of an iButton electronic lock complex circuit made of several circuits, in accordance with the present invention

FIG. 5 illustrates an example of an application for the FIG. 4 circuit diagram, in accordance with the present invention.

FIG. 6 illustrates a flowchart for a general method of predicting failures in electronic and electromechanical equipment, in accordance with the present invention.

FIG. 7 is a table of examples of electronic and electro-mechanical equipment that has had failure precursors identified, in accordance with the present invention.

### BEST MODES FOR CARRYING OUT THE INVENTION

This invention pertains to electrical and electromechanical circuits used in many applications. Electrical circuits consist of electrical components that change voltage and current input and output levels in such a manner as to provide functionality to equipment. Electrical circuits are combined to form complex systems with various voltage and current inputs and outputs. When electrical components begin to fail but the circuit continues to function, the behavior of the circuit can be identified as having a component(s) that are changing operating behavior and are being in the failure start state. A full catastrophic failure does not occur until the functionality of the circuit or system no longer operates within specified performance and functionality. The ability to interpret that a component(s) is starting to change performance behavior by analyzing the circuit behavior, sometimes available in telemetry, is failure prediction or prognostics. Prognostics is failure prediction. Telemetry Prognostics is failure prediction using telemetry to determine that circuit components(s) have changed operating behavior and will fail in the near future. Circuit components may change in operating behavior as the voltage and current values change as up-stream or down-stream components change in electrical properties possibly causing a cascading failure effect since a failed component changes the electrical properties of the circuit. Since a failing component will change the upstream and downstream electrical properties, it may adversely affect up-stream and down-stream components. Prognostics can determine that component and components have begun to change in operating behavior.

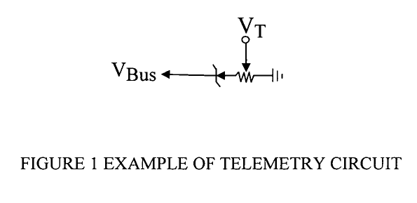

FIG. 1 illustrates a group of electrical components connected together in such a way as to provide a voltage level that indicates the voltage level across the resistor. This voltage level is measured and can be determined to illustrate that the primary circuit is behaving normally according to specifications. When the voltage level changes and is either operating at a new level or is varying in behavior, the output will indicate this is happening and if all other potential sources have been ruled out as to the cause of the change in operating behavior, the circuit can be identified as in the failure state by prognostics.

In FIG. 1, telemetry is available from the V(telemetry) measurement point. V(telemetry) provides the voltage change across the resistor. When telemetry information indicates that component electrical behavior has changed from specified behavior, a component failure is interpreted as at fault. V(telemetry) provides information about many electrical components that are attached to it up-stream and down-stream in the circuit as well as the voltage change across the resistor it is attached to. The indication that telemetry includes the failure signature of component(s) and the ability to interpret the failure signature is the failure prediction technology. When using telemetry for information for predicting a circuit failure from an electrical circuit, it is called Telemetry Prognostics.

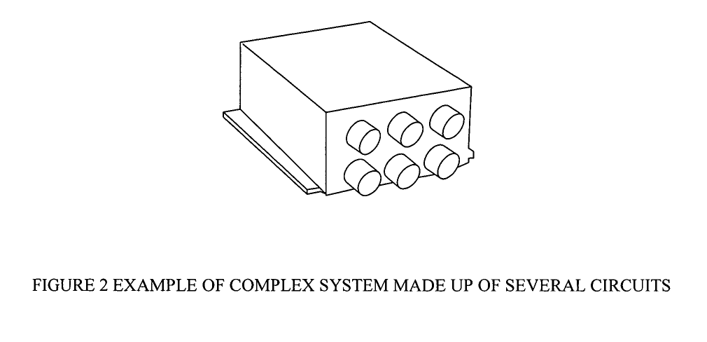

FIG. 2 is an electrical system consisting of many electrical circuits and components with many specified inputs and outputs including telemetry lines. FIG. 2 shows a box of electrical circuits with electrical connectors for providing electrical inputs and outputs including telemetry lines. This electrical box is mounted firmly in place for use and electrical connectors are attached to provide electrical functionality in a system. Since no electrical components are manufactured identically, behave exactly the same and no two identically designed electrical circuits will behave exactly the same, the failure signature for each electrical component used in electrical and electromechanical circuits is unique.

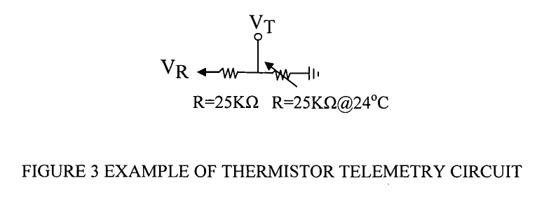

FIG. 3 is an example of a telemetry thermistor circuit for measuring temperature in a circuit. As the temperature changes around the circuit, the value of the 25 KΩ resistor changes and the voltage output changes. This change to a new voltage is measurable and reflects the temperature the circuit is at. The V(temperature) output provides the voltage level that corresponds to a temperature value that the circuit is at. The 25 KΩ resistor with an arrow through it will vary in resistance with temperature. Since V(temperature) is attached to many components, it is a point that the operating behavior of many components can be determined from and a point that many components can be determined to begin operating in a failure state. The ability to identify components that are going to fail in an electrical and electromechanical circuit is failure prediction or prognostics. Prognostics uses the ability to extrapolate forward in time the unspecified behavior of electrical components that are changing in operating behavior that will continue to do so until the circuit that they are in will not function as designed.

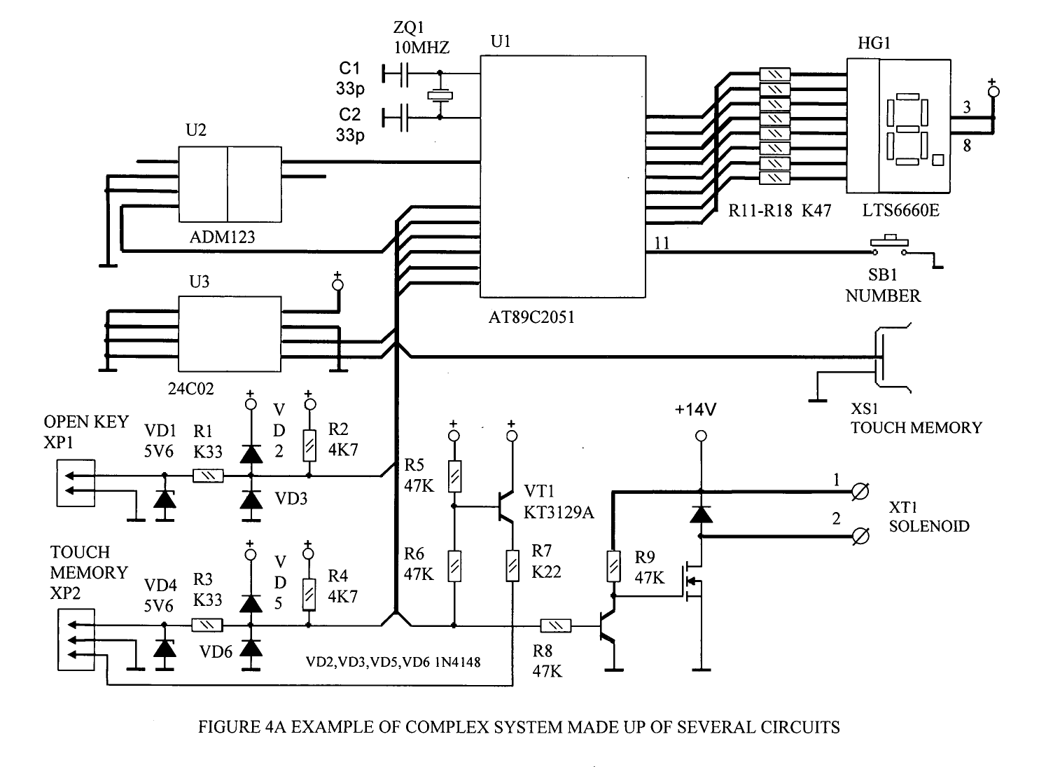

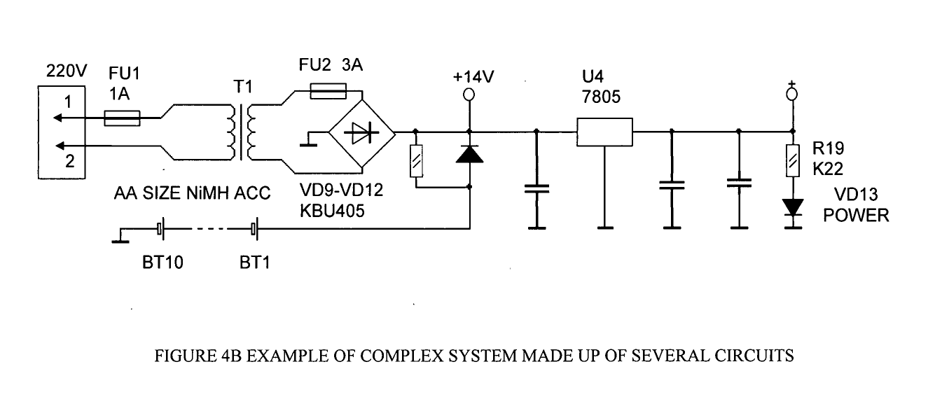

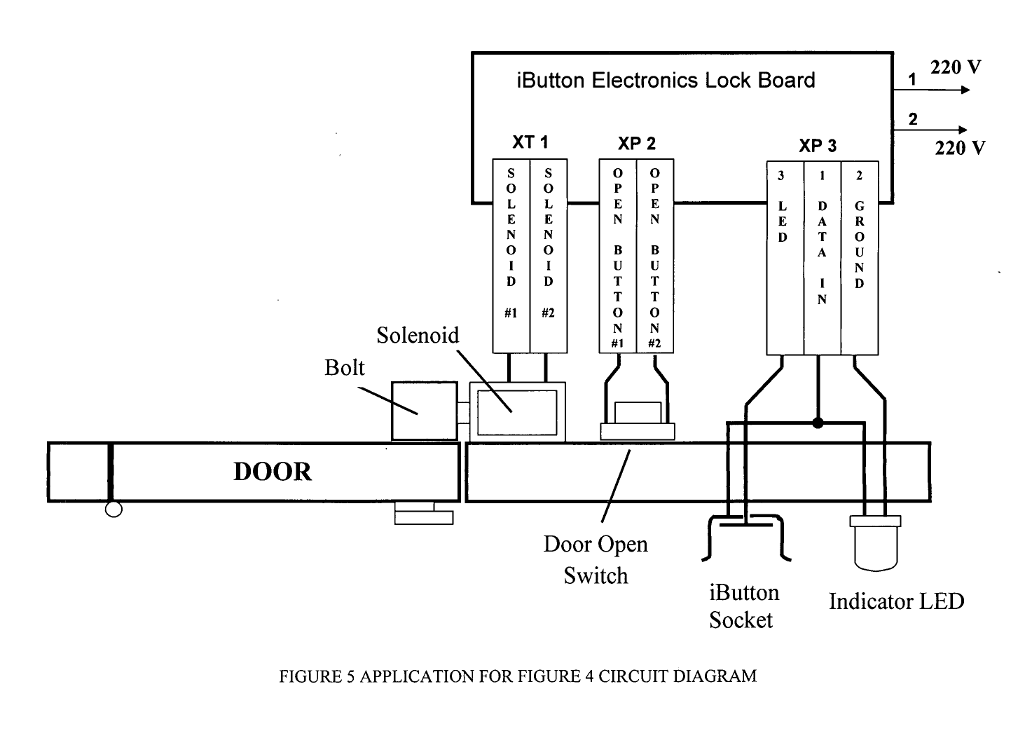

FIG. 4 is an example of an electromechanical complex system made up of electrical circuits It is a schematic of circuits combined to provide a locking mechanism for a door lock. This lock can be unlocked through the entering of the correct pass code into the microcontroller unit manually. This electronic lock can be used with any type of iButtons electronic board, since the only thing needed is the internal serial number that's different for every iButton. The command used to read the serial number is the same for all iButtons. The iButton family code that goes with every iButton can be anything and is calculated as part of the whole serial number. This electronic lock is designed to work stand-alone. What the user sees (outside of the door) is an iButton socket and an LED (light emitting diode). From inside the door, we can open the lock using a simple push button. For the actual lock of the door a solenoid and a bolt are used. A Solenoid must be rated to operate normally at 12 Vdc. An iButtons serial number is stored in memory and can be removed and updated when needed. One master key is used to manage the rest of them. A total number of 9 different keys can be stored in memory at one time. FIG. 4 is a schematic diagram built around an Atmel AT89C2051(U1) microcontroller unit (MCU). The port 1 (P1) of the MCU is used to connect a 7-segment common anode LED display. This LED display will be used on the programming of additional keys. For the same reason a push-button labelled SB1 is connected on P.3.7. Storage of iButtons serial numbers is done on a 24C02 EEPROM (U3). It is connected on P3.4 (SDA) and P3.5 (SCL) of U1. The external iButton socket is connected on port P3.3 via XP2 pin array. The rest of components VD4, R3, VD5 and VD6 are used for protection of MCU ports. One pull-up resistor R4 is used as required from 1-wire protocol. An additional iButton socket is connected parallel with the predefined at pins XS1. This one is used for programming the keys. The door OPEN button is connected on P3.2 through XP1 connector, using the same protection components as above. The solenoid that does the lock is connected on XT1 connector. A solenoid is controlled from a power MOSFET IRF540 (VT3). A diode VD7 is added to protect the MOSFET from voltage strikes due to solenoid inductance. Transistor VT3 is controlled from VT2, which reverses the logic state that's appears on P3.0, so on VT3 we have output 0V and 12V. This additional transistor is useful as it translates the MCU logic levels to 0V and 12V, which are capable to drive the solenoid. An LED is used to indicate the state of the electronic lock, which is controlled from the same pin as the solenoid, using transistor TV1. This LED is connected to the board using the same pin array XP2. But to ensure that the circuit will always work without supervision, an ADM1232 (U2) is added that does the MCU reset pin control. This chip has a counter and voltage test circuits inside. On pin P3.1 the MCU produces pulses when it works right. If for a reason MCU freezes then U2 sends it a reset pulse and work is resumed.

FIG. 5 illustrates an example of an application for the FIG. 4 circuit diagram, in accordance with the present invention.

This electronic lock has its own power supply incorporated, consisting of transformer T1, bridge rectifier VD9-VD12 and voltage regulator U4. As power backup an array of 10 AA batteries is used (BT1-BT10). Total capacity is 800 mAH. When the circuit is connected on main voltage the battery pack is charged via R10 with a current of 20 mA. This current is equal to 0.025C (where C is the batteries capacity) and that's a very small current depending on total current capacity. That puts the battery on a steady charge to compensate for losses among time and no charge completion detection is needed. That can be done as the excess energy is consumed in heat, heat that cannot harm batteries because it's low in quantity.

The electronic lock can register 9 keys, plus one master key. The master's serial number is stored inside the MCU. The rest of keys are stored on the external memory under slot 1 to 9. To add or remove a new key you have to have the master key. The master key can be used to open the door.

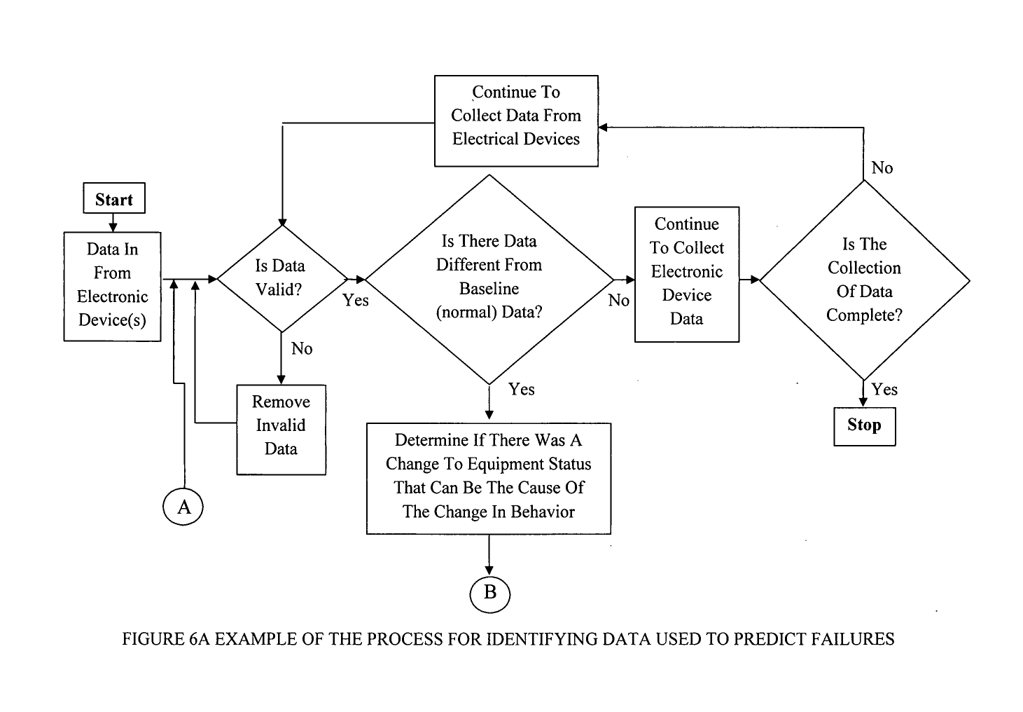

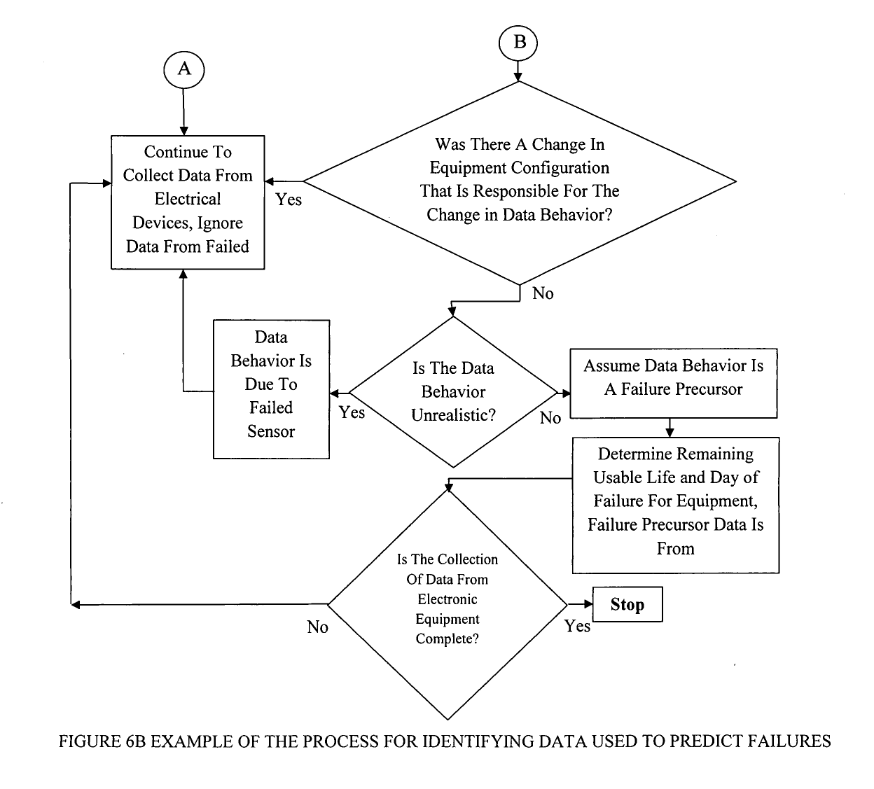

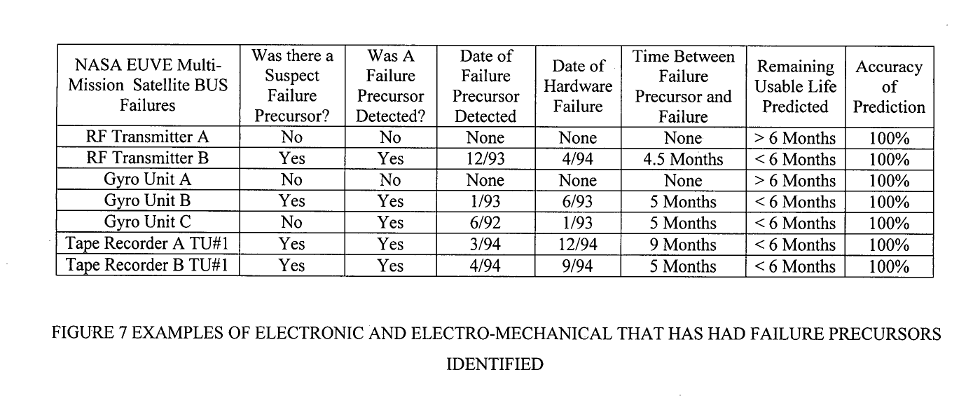

FIG. 6 illustrates a flowchart for a general method of predicting failures in electronic and electromechanical equipment, in accordance with the present invention. The present invention interprets information from electrical circuits as an impending failure signature as they are beginning to fail to operate as specified by the manufacturer. This processing includes removing and/or replacing invalid test information with valid test information, searching all the information for the information that indicates a component is changing behavior, reducing the amount of test information by using statistical sampling to analyze for behavior that indicates a component is failing, presenting the information in graphical form, tabular form or other forms so that a person can interpret the behavior that indicates a failure is occurring. The present invention is able to identify component behavior that is interpreted as behavior indicating future component failure will occur.

FIG. 6 illustrates the process of the method for predicting failures. Data comes in from electronic devices. The data is engineering information which may included for example, volts, amps, current, revolutions per minute and temperature data. This type of engineering information is also herein referred to as telemetry, the remote collection of data. At normal functioning, a baseline is generated. The data indicates a failure when there is a deviation from the normal baseline. Any variation from the normal baseline is a detection of failure and will generate a report regarding failure. The detection can be done by discrimination analysis. The discrimination analysis looks at the data and when there is a variation from the normal data that created the normal baseline, a failure is reported. A user who watches for variations can do discrimination analysis manually. Additionally, computer software can be used where it would watch for variations and report failures.

A collection of data is complete when you have collected enough data, have run out of data and stopped collecting, or you have run out of measurements to quantify from.

The sensors are also herein referred to as a transducer. The sensors are placed in electrical equipment, which are small electrical circuits attached to a primary electrical circuit. The primary electrical circuit is connected to a unit box level type of equipment, for example, a computer.

The monitoring step uses discrimination analysis. Any deviation from the normal baseline is identified as a change. The next step is to look at what induced the change. Other events to be considered as responsible for the change may include for example, reconfiguration of equipment, something was turned on/off, or an equipment power cycle occurred. If it is determined that some other event rather than a failure is responsible for the deviation, then it would not be reported as a failure and the change in the data from the baseline data would be attributed to the other cause. The collection of data would then continue, disregarding the earlier variant data attributed to the other cause.

Electrical components are grouped together to form a transducer circuit that is electrically attached to a primary circuit. Information is collected from the primary circuit. The primary circuit is grouped around other primary circuits that are grouped within another piece of equipment such as a computer. The data collected is generalized as engineering data that is coming from the circuit, for example, voltage, pressure, and temperature.

The sensor also known as the transducer circuit may contain transistors, resistors and capacitors. If one of those failed then that would be a sensor failure. The present invention addresses predicting failures from the primary circuit. If the sensor fails, then it can be ignored since there are several transducers attached to one primary circuit.

When a failure is occurring there is a steady degradation of electrical components and performance becomes unreliable. The ability to determine the remaining usable life and day of failure for equipment failure precursor data correlates the precursor data acquired through the discrimination analysis and compares it to a database of past failures. The correlation of data can determine the day the failure began and the end day when complete failure occurred. This duration is compared against historical duration performance, and a prediction as to how many hours, days or months left before full functional failure is determined.

The ability to determine which components will last the design life and which ones will fail a priori by interpreting their change in operating behavior as an impending failure can be accomplished by installing the components in the circuit that they will operate in and observe the behavior of the electrical characteristics of the circuit in operation. If the circuit current or voltage change with time after the circuit operations has stabilized, the operating characteristics of one or more than one component is changing its operating performance and is interpreted as failing. The ability to predict which components will fail before their design life is complete is called prognostics also known as proactive diagnostics or failure prediction.

In a preferred embodiment, with reference to FIG. 1, the Failure Prediction invention can be used to determine the state of the components that this circuit is embedded with. In the event that an electrical component changes operating behavior that this circuit is attached to, a change in value at the output will be discernable. As depicted in FIG. 3, when the temperature changes from 24° C., the resistance will change in the 2 KΩ resistor and the value that it changes to will determine the temperature of the circuit this temperature measuring circuit is attached to. In FIG. 4, when any component in these circuits change in operating behavior, the up-stream and downstream component will be subjected to other values possibly changing their operating behavior. This change in operating behavior can be measured accurately at many locations in the circuits.

For electrical equipment that cannot be accessed directly for test measurements, telemetry may be used to generate circuit performance behavior information. Telemetry is the generation of circuit behavior information remotely. Telemetry is the science and technology of automatic measurement and transmission of information by wire, radio, or other means from remote sources, as from electrical circuits in space vehicles, to receiving stations at remote sites for recording and analysis.

Circuit telemetry is generated by adding components to electrical circuits that are desired to be evaluated and providing this information remotely. Telemetry circuits become part of the primary circuit but may be electrically isolated so that if a component in the telemetry circuit fails it does not adversely affect the operations of the primary circuit.

The present invention has been particularly shown and described with respect to certain preferred embodiments and features thereof However, it should be readily apparent to those of ordinary skill in the art that various changes and modifications in form and detail may be made without departing from the spirit and scope of the inventions as set forth in the appended claims. The inventions illustratively disclosed herein may be practiced without any element that is not specifically disclosed herein.

1. A method of predicting failures in components comprising the steps of:
installing a component in a circuit,
observing the behavior of the circuit in operation, and
interpreting the change in operating behavior of the circuit.

2. A method as recited in claim 1, wherein the step of observing the behavior of the circuit in operation includes the step of observing the circuit current.

3. A method as recited in claim 2, wherein the step of observing the circuit current further includes the step of observing the circuit after the circuit operation has stabilized.

4. A method as recited in claim 1, wherein the step of observing the behavior of the circuit in operation includes the step of observing the circuit voltage.

5. A method as recited in claim 4, wherein the step of observing the circuit voltage further includes the step of observing the circuit after the circuit operation has stabilized.

6. A method as recited in claim 1, wherein the step of interpreting the change in operating behavior of the circuit further includes the step whereby the interpretation of the operating characteristics of at least one component changing its operating performance is interpreted as a failure.

7. A method of predicting failures in components comprising the steps of:
installing a component in a circuit, generating circuit behavior information remotely, and
interpreting the change in operating behavior of the circuit.

8. The method as recited in claim 7, wherein the step of generating circuit behavior remotely includes the step of using telemetry.

9. The method as recited in claim 8, wherein the step of using telemetry further includes the automatic measurement and transmission of said information.

10. The method as recited in claim 9 wherein the step of automatic measurement and transmission of said information is selected from a group consisting of wire or radio.

11. A method as recited in claim 7, wherein the step of interpreting the change in operating behavior of the circuit further includes the step whereby the interpretation of the operating characteristics of at least one component changing its operating performance is interpreted as a failure.
